(19) United States
(12) Patent Application Publication
(10) Pub. No.: US 2026/0114318 A1
(43) Pub. Date: Apr. 23, 2026

(54) SEMICONDUCTOR DEVICE

(71) Applicant: SUMITOMO ELECTRIC INDUSTRIES, LTD., Osaka (JP)

(72) Inventors: Tomoki IKEDA, Osaka (JP); Yoshisumi KAWABATA, Osaka (JP)

(73) Assignee: SUMITOMO ELECTRIC INDUSTRIES, LTD., Osaka (JP)

(21) Appl. No.: 19/115,523

(22) PCT Filed: Sep. 6, 2023
(86) PCT No.: PCT/JP2023/032467

§ 371 Date: Mar. 26, 2025

(30) Foreign Application Priority Data
Oct. 7, 2022 (JP) 2022-162390

(51) Int. Cl. H10W 76/136; H10D 80/20; H10W 40/25; H10W 74/10; H10W 90/00; H10W 90/10

(52) U.S. Cl. CPC H10W 76/136; H10D 80/251; H10W 40/255; H10W 74/114; H10W 90/10; H10W 90/754

(57) ABSTRACT

A semiconductor device includes: a substrate with a circuit pattern: a semiconductor chip mounted on the circuit pattern and electrically connected to the circuit pattern; a frame member including a wall portion; and a plate-shaped terminal electrically connected to the circuit pattern. The wall portion surrounds the substrate. The terminal includes a first region attached to the wall portion, and a second region continuous to the first region and located inside the frame member. A distance between an inner wall surface of the wall portion and the circuit pattern is 500 μm or less. The second region is directly connected to the circuit pattern.

### TECHNICAL FIELD

The present disclosure relates to a semiconductor device. This application claims priority to Japanese Patent Application No. 2022-162390, which was filed on Oct. 7, 2022, and is incorporated herein by reference in its entirety.

### BACKGROUND ART

A semiconductor device including a substrate with a metal pattern, a case, a resin filling the case, and a semiconductor element electrically connected to the metal pattern is disclosed (see, for example, Patent Literature 1). In the semiconductor device disclosed in Patent Literature 1, the case includes a wall portion extending upward, and a projecting portion connected to the wall portion and projecting toward the center of the substrate. The projecting portion includes a first surface that is an inclined surface, is connected to the tip of the projecting portion, and becomes closer to the substrate as the distance from the tip of the projecting portion increases, and a second surface that is connected to the lower side of the first surface and is more perpendicular to the upper surface of the substrate than the first surface is. A metal pattern is located immediately under the first surface.

### CITATION LIST

### Patent Literature

Patent Literature 1: Japanese Patent Application Publication No. 2020-14025

### SUMMARY OF INVENTION

A semiconductor device according to the present disclosure includes: a substrate with a circuit pattern; a semiconductor chip mounted on the circuit pattern and electrically connected to the circuit pattern; a frame member including a wall portion; and a plate-shaped terminal electrically connected to the circuit pattern. The wall portion surrounds the substrate. The terminal includes a first region attached to the wall portion, and a second region continuous to the first region and located inside the frame member. A distance between an inner wall surface of the wall portion and the circuit pattern is 500 μm or less. The second region is directly connected to the circuit pattern.

### BRIEF DESCRIPTION OF DRAWINGS

FIG. 1 is a schematic plan view of a semiconductor device according to a first embodiment when seen in a thickness direction of a substrate.

FIG. 2 is a schematic cross-sectional view partially illustrating the semiconductor device in FIG. 1.

FIG. 3 is a schematic cross-sectional view illustrating an intermediate stage of a fabrication process for the semiconductor device.

FIG. 4 is a schematic cross-sectional view illustrating an intermediate stage of the fabrication process for the semiconductor device.

FIG. 5 is a schematic cross-sectional view illustrating an intermediate stage of the fabrication process for the semiconductor device.

FIG. 6 is a schematic perspective view partially illustrating a semiconductor device according to a second embodiment.

### DESCRIPTION OF EMBODIMENTS

### Technical Problem

In recent years, semiconductor devices have faced demands not only for miniaturization but also for reduced inductance.

It is therefore an object of the present disclosure to provide a semiconductor device that facilitates miniaturization and can reduce inductance.

### Effects of the Disclosure

Such a semiconductor device easily achieve miniaturization and can reduce inductance.

### Description of Embodiments of the Present Disclosure

First, embodiments of the present disclosure will be listed and described. (1) A semiconductor device according to the present disclosure includes: a substrate with a circuit pattern; a semiconductor chip mounted on the circuit pattern and electrically connected to the circuit pattern; a frame member including a wall portion; and a plate-shaped terminal electrically connected to the circuit pattern. The wall portion surrounds the substrate. The terminal includes a first region attached to the wall portion, and a second region continuous to the first region and located inside the frame member. A distance between an inner wall surface of the wall portion and the circuit pattern is 500 μm or less. The second region is directly connected to the circuit pattern.

In this semiconductor device, the distance between the inner wall surface of the wall portion and the circuit pattern is 500 μm or less, and the second region of the terminal is directly connected to the circuit pattern. Thus, the device configuration can be simplified to be miniaturized. In addition, members such as wires are unnecessary to connect the terminal to the circuit pattern so that inductance can be reduced without the need for wiring. The thus-configured semiconductor device can be easily miniaturized and can reduce inductance.
(2) A semiconductor device according to the present disclosure includes: a substrate with a circuit pattern; a semiconductor chip mounted on the circuit pattern and electrically connected to the circuit pattern; a frame member including a wall portion; and a plate-shaped terminal electrically connected to the circuit pattern. The wall portion surrounds the substrate. The terminal includes a third region attached to the wall portion, a fourth region located inside the frame member and directly connected to the circuit pattern, and a fifth region located between the third region and the fourth region. A distance between an inner wall surface of the wall portion and the circuit pattern is 500 μm or less. A gap is present between the fifth region and the circuit pattern. The fifth region includes a through hole penetrating the substrate in a thickness direction of the substrate.

In this semiconductor device, the distance between the inner wall surface of the wall portion and the circuit pattern is 500 μm or less, and the fourth region of the terminal is directly connected to the circuit pattern. Thus, the device configuration can be simplified to be miniaturized. In addition, members such as wires are unnecessary to connect the terminal to the circuit pattern so that inductance can be reduced without the need for wiring. The thus-configured semiconductor device can be easily miniaturized and can reduce inductance. In the semiconductor device described above, the fifth region having the gap between the fifth region and the circuit pattern has the through hole penetrating the substrate in the thickness direction thereof. Thus, even if bubbles are mixed in filling a frame member with an encapsulant so that the gap includes bubbles, bubbles are released through the through hole in the fifth region during release of bubbles, thereby eliminating bubbles from the encapsulant. Accordingly, it is possible to suppress durability degradation of the semiconductor device by reducing retention of bubble in a lower portion of the terminal. As a result, the semiconductor device can enhance reliability.

In the semiconductor device (1) or (2), the distance between the inner wall surface of the wall portion and the circuit pattern may be 100 μm or less, from the viewpoint of further suppressing generation of bubbles.
(3) In the semiconductor device of (1) or (2), an inner wall surface of the wall portion may be in contact with the circuit pattern. With this configuration, the inner wall surface of the wall portion is in close contact with the circuit pattern, thereby reducing possibility that resin containing bubbles is present between the inner wall surface of the wall portion and the circuit pattern. As a result, durability degradation is further suppressed so that reliability can be thereby further enhanced.
(4) In the semiconductor device of any one of (1) to (3), at least one of the second region and the circuit pattern or the fourth region and the circuit pattern may be connected to each other by welding, ultrasonic bonding, a conductive binder, or soldering.
(5) The semiconductor device of any one of (1) to (4) may further include a base plate which contacts the substrate and to which the frame member is attached. This base plate is effectively used for fixing the frame member and for heat dissipation from the semiconductor chip and other components.
(6) The semiconductor device of any one of (1) to (5) may further include an encapsulant that fills space surrounded by the wall portion. This encapsulant can suppress degradation of durability of the semiconductor device and further enhance reliability.
(7) In the semiconductor device of any one of (1) to (6), the terminal may include a control terminal that controls operation of the semiconductor chip. This configuration can reduce inductance in the control terminal.
(8) In the semiconductor device of any one of (1) to (6), the terminal may include a main terminal electrically connecting the semiconductor device to outside. This configuration can reduce inductance in the main terminal.
(9) In the semiconductor device of any one of (1) to (8), an outer wall surface of the substrate may be in contact with the inner wall surface of the wall portion. With this configuration, the outer wall surface of the substrate is fitted in the inner wall surface of the wall portion to facilitate attachment of the frame member to the substrate. In addition, positioning of the substrate to the frame member can be further ensured.
(10) In the semiconductor device of any one of (1) to (9), at least one of the first region or the third region may include a portion inserted in the wall portion. In this manner, terminals can be fixed to wall portions of the frame member beforehand, and thus, the terminals can be more securely attached to the frame member.
(11) In the semiconductor device of any one of (1) to (10), the semiconductor chip may include a SiC transistor chip. In this configuration, since this semiconductor chip includes silicon carbide (SiC) as a semiconductor layer, the semiconductor chip can be switched at high speed. Thus, the semiconductor chip is preferable for the semiconductor device according to the present disclosure that switches current paths.
(12) In the semiconductor device of any one of (1) to (11), the inner wall surface of the wall portion may extend in a thickness direction of the substrate. With this configuration, in filling the inside of the frame member with the encapsulant, the possibility of inhibiting detachment in releasing enclosed bubbles can be reduced. The thus-configured semiconductor device can suppress durability degradation and has high reliability.

### Detailed Description of Embodiment of the Present Disclosure

Embodiments of the semiconductor device according to the present disclosure will be described with reference to the drawings. In the following drawings, the same or corresponding parts are denoted by the same reference numerals, and the description

### First Embodiment

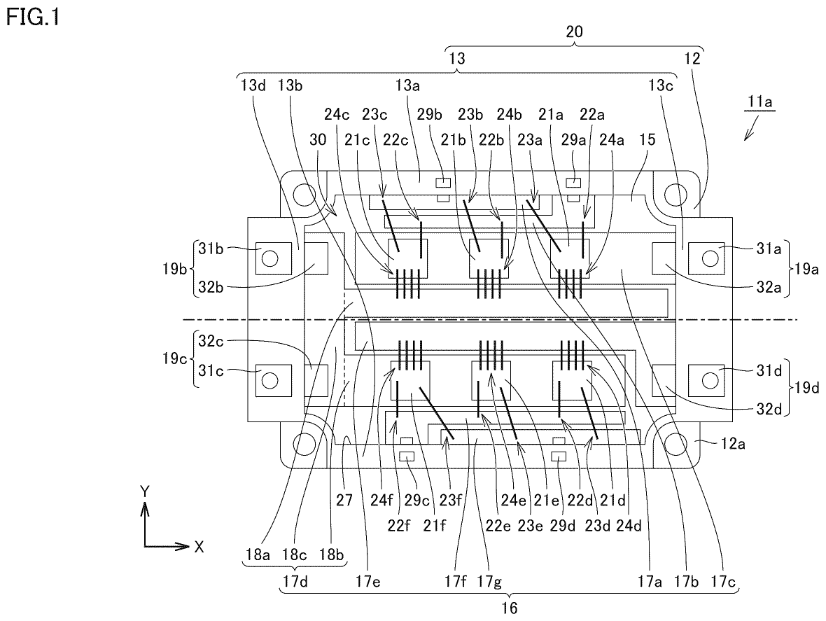

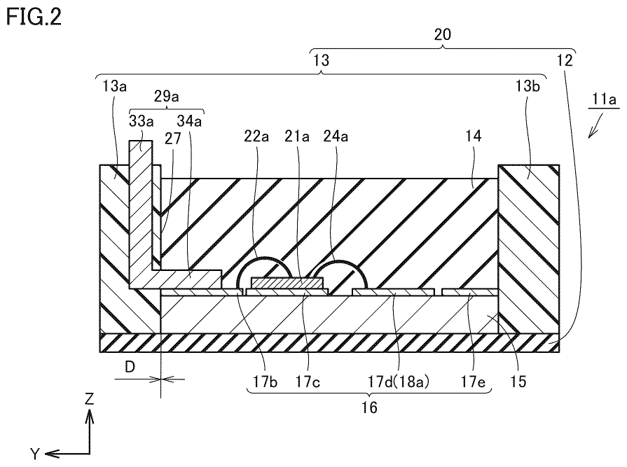

A semiconductor device according to a first embodiment of the present disclosure will be described. FIG. 1 is a schematic plan view of the semiconductor device according to the first embodiment when seen in the thickness direction of a substrate. FIG. 2 is a cross-sectional view schematically illustrating a portion of the semiconductor device illustrated in FIG. 1. FIG. 2 is a schematic cross-sectional view taken in a Y-Z plane. FIG. 2 illustrates a configuration with some components shown in FIG. 1 omitted for clarity and ease of understanding. In FIG. 1 and the following drawings, the thickness direction of the substrate is defined as a Z direction.

With reference to FIGS. 1 and 2, a semiconductor device 11a according to a first embodiment includes a base plate 12, a frame member 13, a substrate 15 with a circuit pattern 16, four terminals of a terminal 19a (main terminal 19a), a terminal 19b (main terminal 19b), a terminal 19c (main terminal 19c), and a terminal 19d (main terminal 19d), four terminals of a terminal 29a (control terminal 29a), a terminal 29b (control terminal 29b), a terminal 29c (control terminal 29c), and a terminal 29d (control terminal 29d), and six semiconductor chips of a semiconductor chip 21a, a semiconductor chip 21b, a semiconductor chip 21c, a semiconductor chip 21d, a semiconductor chip 21e, and a semiconductor chip 21f.

The base plate 12 is made of a metal. The base plate 12 is made of, for example, copper. The base plate 12 is a so-called heat dissipation plate and used for heat dissipation from the semiconductor chip 21a, the semiconductor chip 21b, the semiconductor chip 21c, the semiconductor chip 21d, the semiconductor chip 21e, and the semiconductor chip 21f. The outer shape of the base plate 12 is a rectangle whose side extending in the X direction is a longer side and whose side extending in the Y direction is a shorter when seen in the thickness direction (Z direction), and the four corners of the rectangle are rounded.

The substrate 15 with the circuit pattern 16 is located on the base plate 12. Specifically, the substrate 15 is placed on a first surface 12a located in the thickness direction of the base plate 12. The substrate 15 is insulative. Examples of the material for the substrate 15 include Al₂O₃, AIN, and Si₃N₄. The thickness direction of the base plate 12 and the thickness direction of the substrate 15 are both the Z direction. The outer shape of the substrate 15 is a rectangle whose side extending in the X direction is a long side and whose side extending in the Y direction is a short side when seen in the thickness direction of the substrate 15. A configuration of the circuit pattern 16 will be described in detail later.

The frame member 13 rises from the first surface 12a of the base plate 12 and surrounds the substrate 15. The frame member 13 includes a wall portion 13a (first wall portion 13a), a wall portion 13b (second wall portion 13b), a wall portion 13c (third wall portion 13c), and a wall portion 13d (fourth wall portion 13d). The first wall portion 13a, the second wall portion 13b, the third wall portion 13c, and the fourth wall portion 13d surround the substrate 15. Inner wall surfaces 27 of the first wall portion 13a, the second wall portion 13b, the third wall portion 13c, and the fourth wall portion 13d extend in the thickness direction of the substrate 15, that is, in the Z direction. The first wall portion 13a and the second wall portion 13b face each other in the Y direction. The third wall portion 13c and the fourth wall portion 13d face each other in the X direction. The frame member 13 is made of an insulative resin, for example. The frame member 13 is fixed to the base plate 12 with, for example, an adhesive. The base plate 12 and the frame member 13 constitute a case 20 included in the semiconductor device 11a. Space 30 in the case 20 is filled with a resin encapsulant 14.

The circuit pattern 16 is located on the substrate 15. The circuit pattern 16 is made of, for example, copper. The circuit pattern 16 includes seven circuit plates of a circuit plate 17a, a circuit plate 17b, a circuit plate 17c, a circuit plate 17d, a circuit plate 17e, a circuit plate 17f, and a circuit plate 17g. That is, the circuit pattern 16 is constituted by the seven circuit plates of the circuit plate 17a, the circuit plate 17b, the circuit plate 17c, the circuit plate 17d, the circuit plate 17e, the circuit plate 17f, and the circuit plate 17g on the substrate 15. The circuit plate 17a has a band shape extending in the X direction and is in contact with the first wall portion 13a. The circuit plate 17b is located closer to the second wall portion 13b than the circuit plate 17a is, and includes a band shape portion elongated in the X direction. The circuit plate 17b includes a portion in contact with the first wall portion 13a. The circuit plate 17c has a band shape elongated in the X direction and is in contact with the third wall portion 13c. A configuration of the circuit plate 17d will be described later. The circuit plate 17e includes a band-shaped portion elongated in the X direction and a portion in contact with the third wall portion 13c. The circuit plate 17f includes a band-shaped portion elongated in the X direction. The circuit plate 17f has a portion in contact with the second wall portion 13b. The circuit plate 17g has a band shape extending in the X direction and is in contact with the second wall portion 13b. The circuit plate 17a, the circuit plate 17b, the circuit plate 17c, the circuit plate 17d, the circuit plate 17e, the circuit plate 17f, and the circuit plate 17g are arranged with intervals.

The circuit plate 17d includes a band-shape first portion 18a extending in the X direction, a band-shape second portion 18b extending in the X direction similarly, and a third portion 18c having a band shape extending in the Y direction and coupling the first portion 18a and the second portion 18b. The first portion 18a and the second portion 18b are disposed with an interval in the Y direction. In the Y direction, the circuit plate 17c is located between the first portion 18a and the circuit plate 17b. In the Y direction, the circuit plate 17e is located between the first portion 18a and the second portion 18b. The third portion 18c is in contact with the fourth wall portion 13d.

Each of the main terminal 19a, the main terminal 19b, the main terminal 19c, and the main terminal 19d has a plate shape and made of a metal. In this embodiment, the main terminal 19a is a P-terminal, the main terminal 19b and the main terminal 19c are O-terminals, and the main terminal 19d is an N-terminal. Each of the main terminal 19a, the main terminal 19b, the main terminal 19c, and the main terminal 19d has a bent band shape. In this embodiment, each of the main terminal 19a, the main terminal 19b, the main terminal 19c, and the main terminal 19d is formed by, for example, bending a band-shaped copper plate. The main terminal 19a and the main terminal 19d are attached to the third wall portion 13c with an interval in the Y direction, and the main terminal 19b and the main terminal 19c are attached to the fourth wall portion 13d with an interval in the Y direction. The semiconductor device 11a obtains electrical connection to the outside through the main terminal 19a, the main terminal 19b, the main terminal 19c, and the main terminal 19d. Each of the main terminal 19a, the main terminal 19b, the main terminal 19c, and the main terminal 19d includes a portion that is exposed to the space 30 in the case 20 from the inner wall surface 27 of the frame member 13. By using this portion, wires as connection members are electrically connected.

The main terminal 19a includes a first region 31a attached to the third wall portion 13c and a second region 32a located inside the frame member 13. In this embodiment, the first region 31a is embedded in the third wall portion 13c. The main terminal 19b includes a first region 31b attached to the fourth wall portion 13d and a second region 32b located inside the frame member 13. In this embodiment, the first region 31b is embedded in the fourth wall portion 13d. The main terminal 19c includes a first region 31c attached to the fourth wall portion 13d and a second region 32c located inside the frame member 13. In this embodiment, the first region 31c is embedded in the fourth wall portion 13d. The main terminal 19d includes a first region 31d attached to the third wall portion 13c and a second region 32d located inside the frame member 13. In this embodiment, the first region 31d is embedded in the third wall portion 13c. Each of the main terminal 19a, the main terminal 19b, the main terminal 19c, and the main terminal 19d is inserted in the frame member 13. That is, the main terminal 19a, the main terminal 19b, the main terminal 19c, and the main terminal 19d are attached to the frame member 13 by insert molding.

Each of the semiconductor chip 21a, the semiconductor chip 21b, the semiconductor chip 21c, the semiconductor chip 21d, the semiconductor chip 21e, the semiconductor chip 21f includes SiC as a semiconductor layer. The semiconductor chip 21a, the semiconductor chip 21b, the semiconductor chip 21c, the semiconductor chip 21d, the semiconductor chip 21e, the semiconductor chip 21f are SiC transistor chips. In this embodiment, the semiconductor chip 21a, the semiconductor chip 21b, the semiconductor chip 21c, the semiconductor chip 21d, the semiconductor chip 21e, and the semiconductor chip 21f are, for example, metal-oxide-semiconductor field-effect transistors (MOSFETs). The semiconductor chip 21a, the semiconductor chip 21b, and the semiconductor chip 21c are arranged on the circuit plate 17c with intervals in the X direction. The semiconductor chip 21a, the semiconductor chip 21b, and the semiconductor chip 21c are electrically connected to the circuit plate 17c by, for example, soldering. The semiconductor chip 21d, the semiconductor chip 21e, and the semiconductor chip 21f are arranged on the second portion 18b of the circuit plate 17d with intervals in the X direction. The semiconductor chip 21d, the semiconductor chip 21e, and the semiconductor chip 21f are electrically connected to the circuit plate 17d by, for example, soldering.

Each of the control terminal 29a, the control terminal 29b, the control terminal 29c, and the control terminal 29d also has a plate shape and is made of a metal. In this embodiment, the control terminal 29a is a gate terminal, the control terminal 29b is a source sense terminal, the control terminal 29c is a gate terminal, and the control terminal 29d is a source sense terminal. Each of the control terminal 29a, the control terminal 29b, the control terminal 29c, and the control terminal 29d has a bent band shape. In this embodiment, each of the control terminal 29a, the control terminal 29b, the control terminal 29c, and the control terminal 29d is formed by, for example, bending a band-shaped copper plate. The control terminal 29a and the control terminal 29b are attached to the first wall portion 13a with an interval in the X direction, and the control terminal 29c and the control terminal 29d are attached to the second wall portion 13b with an interval in the X direction. The semiconductor device 11a controls operation of the six semiconductor chips of the semiconductor chip 21a, the semiconductor chip 21b, the semiconductor chip 21c, the semiconductor chip 21d, the semiconductor chip 21e, and the semiconductor chip 21f by using the control terminal 29a, the control terminal 29b, the control terminal 29c, and the control terminal 29d. Each of the control terminal 29a, the control terminal 29b, the control terminal 29c, and the control terminal 29d includes a portion that is exposed to the space 30 in the case 20 from the inner wall surface 27 of the frame member 13. By using this portion, wires as connection members are electrically connected.

The control terminal 29a includes a first region 33a attached to the first wall portion 13a and a second region 34a located inside the frame member 13. Similarly, the control terminal 29b includes a first region attached to the first wall portion 13a and a second region located inside the frame member 13. Each of the control terminal 29c and the control terminal 29d also includes a first region attached to the second wall portion 13b and a second region located inside the frame member 13. The control terminal 29a, the control terminal 29b, the control terminal 29c, and the control terminal 29d are inserted in the frame member 13. That is, the control terminal 29a, the control terminal 29b, the control terminal 29c, and the control terminal 29d are attached to the frame member 13 by insert molding.

A gate pad of the semiconductor chip 21a is electrically connected to the circuit plate 17b by a wire 22a. A source pad of the semiconductor chip 21a is electrically connected to the circuit plate 17a by a wire 23a. The source pad of the semiconductor chip 21a is electrically connected to the first portion 18a of the circuit plate 17d by a plurality of wires 24a. A gate pad of the semiconductor chip 21b is electrically connected to the circuit plate 17b by a wire 22b. A source pad of the semiconductor chip 21b is electrically connected to the circuit plate 17a by a wire 23b. The source pad of the semiconductor chip 21b is electrically connected to the first portion 18a of the circuit plate 17d by a plurality of wires 24b. A gate pad of the semiconductor chip 21c is electrically connected to the circuit plate 17b by a wire 22c. A source pad of the semiconductor chip 21c is electrically connected to the circuit plate 17a by a wire 23c. The source pad of the semiconductor chip 21c is electrically connected to the first portion 18a of the circuit plate 17d by a plurality of wires 24c. A gate pad of the semiconductor chip 21d is electrically connected to the circuit plate 17f by a wire 22d. A source pad of the semiconductor chip 21d is electrically connected to the circuit plate 17g by a wire 23d. The source pad of the semiconductor chip 21d is electrically connected to the circuit plate 17e by a plurality of wires 24d. A gate pad of the semiconductor chip 21e is electrically connected to the circuit plate 17f by a wire 22e. A source pad of the semiconductor chip 21e is electrically connected to the circuit plate 17g by a wire 23e. The source pad of the semiconductor chip 21d is electrically connected to the circuit plate 17e by a wire 24e. A gate pad of the semiconductor chip 21f is electrically connected to the circuit plate 17f by a wire 22f. A source pad of the semiconductor chip 21f is electrically connected to the circuit plate 17g by a wire 23f. The source pad of the semiconductor chip 21f is electrically connected to the circuit plate 17e by a plurality of wires 24f.

A distance D between the inner wall surface 27 of the wall portion 13a (first wall portion 13a) and the circuit pattern 16 is 500 μm or less. The distance D is a distance in the Y direction. In this embodiment, the distance between the inner wall surface 27 of the first wall portion 13a and the circuit pattern 16 is 0 μm. In other words, the inner wall surface 27 of the first wall portion 13a is in contact with the circuit pattern 16.

The second region 34a of the control terminal 29a is directly connected to the circuit pattern 16. Specifically, the second region 34a is directly connected to the circuit plate 17b of the circuit pattern 16 by ultrasonic bonding. Similarly, each of the control terminal 29b, the control terminal 29c, the control terminal 29d, the main terminal 19a, the main terminal 19b, the main terminal 19c, and the main terminal 19d is also directly connected to the circuit pattern 16 by ultrasonic bonding.

A flow of current will be briefly described below. In a case where control by using the control terminal 29a, the control terminal 29b, the control terminal 29c, and the control terminal 29d turns the semiconductor chip 21a, the semiconductor chip 21b, and the semiconductor chip 21c on so that electrical connection between the main terminal 19a and the main terminal 19b is on and electrical connection between the main terminal 19c and the main terminal 19d is off, current flows from the main terminal 19a to the circuit plate 17c of the circuit pattern 16, flows in the semiconductor chip 21a, the semiconductor chip 21b, and the semiconductor chip 21c in the on state, flows in the wires 24a, the wire 24b, and the wire 24c, flows in the first portion 18a of the circuit plate 17d of the circuit pattern 16, and flows in the third portion 18c of the circuit plate 17d of the circuit pattern 16, and the main terminal 19b. At this time, no current flows in the second portion 18b of the circuit plate 17d of the circuit pattern 16 on which the semiconductor chip 21d, the semiconductor chip 21e, and the semiconductor chip 21f in the off state are mounted.

Next, in a case where control by using the control terminal 29a, the control terminal 29b, the control terminal 29c, and the control terminal 29d turns the semiconductor chip 21d, the semiconductor chip 21e, and the semiconductor chip 21f on so that electrical connection between the main terminal 19c and the main terminal 19d is on and electrical connection between the main terminal 19a and the main terminal 19b is off, current flows from the main terminal 19c to the third portion 18c of the circuit plate 17d of the circuit pattern 16, flows in the second portion 18b, flows in the semiconductor chip 21d, the semiconductor chip 21e, and the semiconductor chip 21f in the on state, flows in the wires 24d, the wire 24e, and the wire 24f, flows in the circuit plate 17e of the circuit pattern 16, and flows in the main terminal 19d. At this time, no current flows in the first portion 18a of the circuit plate 17d of the circuit pattern 16 on which the semiconductor chip 21a, the semiconductor chip 21b, and the semiconductor chip 21c in the off state are mounted.

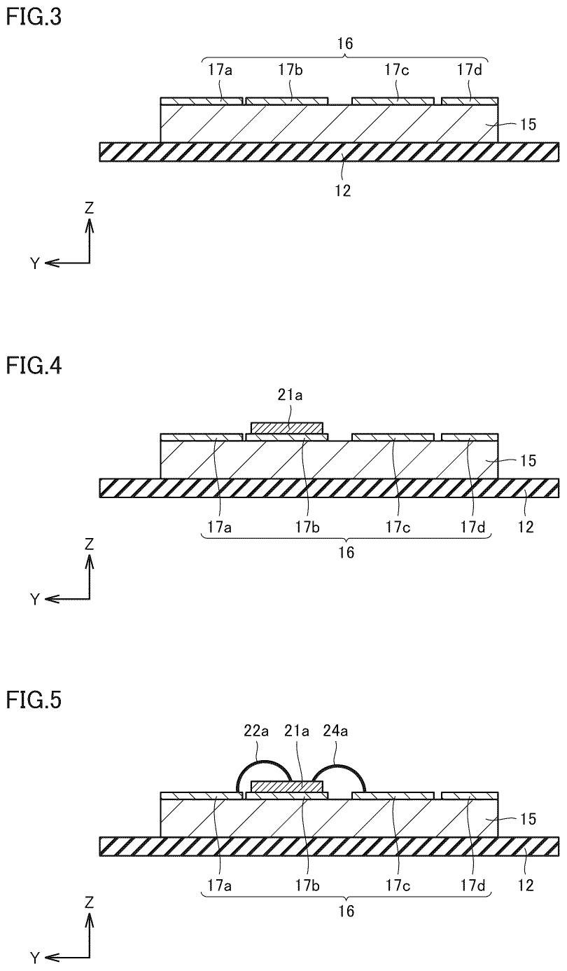

A method for fabricating the semiconductor device 11a described above will be described briefly. FIGS. 3, 4, and 5 are schematic cross-sectional views each illustrating an intermediate stage of a fabrication process of the semiconductor device 11a. First, as illustrated in FIG. 3, the substrate 15 with the circuit pattern 16 and the base plate 12 are bonded with an adhesive (not shown). Next, as illustrated in FIG. 4, the semiconductor chip 21a is soldered onto the circuit pattern 16. At this time, a drain pad of the semiconductor chip 21a is electrically connected to the circuit pattern 16. Thereafter, as illustrated in FIG. 5, wire bonding is performed with a bond tool so that members are electrically connected to one another by wires. Subsequently, the frame member 13 in which the control terminal 29a and other components are insert molded and attached is bonded to the base plate 12 with an adhesive. Then, the second region 34a of the control terminal 29a is ultrasonic bonded to the circuit pattern 16. In this manner, the control terminal 29a is directly connected to the circuit pattern 16. Thereafter, as illustrated in FIG. 2, the space 30 defined by the base plate 12 and the frame member 13 is filled with the encapsulant 14 and sealed. In this manner, the semiconductor device 11a is fabricated.

In the thus-fabricated semiconductor device 11a, the distance D between the inner wall surfaces 27 of the wall portion 13a, the wall portion 13b, the wall portion 13c, and the wall portion 13d and the circuit pattern 16 is 500 μm or less, the second region 32a, the second region 32b, the second region 32c, the second region 32d, and the second region 34a of the control terminal 29a, the control terminal 29b, the control terminal 29c, and the control terminal 29d are directly connected to the circuit pattern 16. Thus, the device configuration is simplified to achieve miniaturization. In addition, members such as wires are unnecessary to connect the control terminal 29a, the control terminal 29b, the control terminal 29c, and the control terminal 29d to the circuit pattern 16 so that inductance can be reduced without the need for wiring. The thus-configured semiconductor device 11a can be easily miniaturized and can reduce inductance.

In this embodiment, the inner wall surface 27 of the wall portion 13a is in contact with the circuit pattern 16. Thus, the inner wall surface 27 of the wall portion 13a is in close contact with the circuit pattern 16, thereby reducing possibility that resin containing bubbles is present between the inner wall surface 27 of the wall portion 13a and the circuit pattern 16. As a result, durability degradation is further suppressed so that reliability can be thereby further enhanced.

In this embodiment, the second region 34a and the circuit pattern 16 are connected by ultrasonic bonding. Such connection enables connection between the second region 34a and the circuit pattern 16, while further ensuring conductivity.

This embodiment includes the base plate 12 which contacts the substrate 15 and to which the frame member 13 is attached. This base plate 12 is effectively used for fixing the frame member 13 and for heat dissipation from the semiconductor chip 21a and other components.

This embodiment includes the encapsulant 14 that fills space surrounded by the wall portion 13a, the wall portion 13b, the wall portion 13c, and the wall portion 13d. This encapsulant 14 can suppress degradation of durability of the semiconductor device 11a and further enhance reliability.

In this embodiment, the terminals include the control terminal 29a, the control terminal 29b, the control terminal 29c, and the control terminal 29d for controlling operation of the semiconductor chip 21a, the semiconductor chip 21b, the semiconductor chip 21c, the semiconductor chip 21d, the semiconductor chip 21e, and the semiconductor chip 21f. Thus, inductance in the control terminal 29a, the control terminal 29b, the control terminal 29c, and the control terminal 29d can be reduced.

In this embodiment, the terminals include the main terminal 19a, the main terminal 19b, the main terminal 19c, and the main terminal 19d electrically connecting the semiconductor device 11a to the outside. Thus, inductance in the main terminal 19a, the main terminal 19b, the main terminal 19c, and the main terminal 19d can be reduced.

In this embodiment, the outer wall surface of the substrate 15 is in contact with the inner wall surfaces 27 of the wall portion 13a, the wall portion 13b, the wall portion 13c, and the wall portion 13d. Thus, the outer wall surface of the substrate 15 is fitted in the inner wall surfaces 27 of the wall portion 13a, the wall portion 13b, the wall portion 13c, and the wall portion 13d to facilitate attachment of the frame member 13 to the substrate 15. In addition, positioning of the substrate 15 to the frame member 13 can be further ensured.

In this embodiment, the first region 31a, the first region 31b, the first region 31c, and the first region 31d include portions inserted in the wall portion 13a, the wall portion 13b, the wall portion 13c, and the wall portion 13d. Accordingly, the main terminal 19a, the main terminal 19b, the main terminal 19c, the main terminal 19d, the control terminal 29a, the control terminal 29b, the control terminal 29c, and the control terminal 29d can be fixed to the wall portion 13a, the wall portion 13b, the wall portion 13c, and the wall portion 13d of the frame member 13 beforehand, thereby further ensuring attachment of the main terminal 19a, the main terminal 19b, the main terminal 19c, the main terminal 19d, the control terminal 29a, the control terminal 29b, the control terminal 29c, and the control terminal 29d to the frame member 13.

In this embodiment, the inner wall surfaces 27 of the wall portion 13a, the wall portion 13b, the wall portion 13c, and the wall portion 13d extend in the thickness direction of the substrate 15. Thus, in filling the inside of the frame member 13 with the encapsulant 14, the possibility of inhibiting detachment in releasing enclosed bubbles can be reduced. The thus-configured semiconductor device 11a can suppress durability degradation and has high reliability.

### Second Embodiment

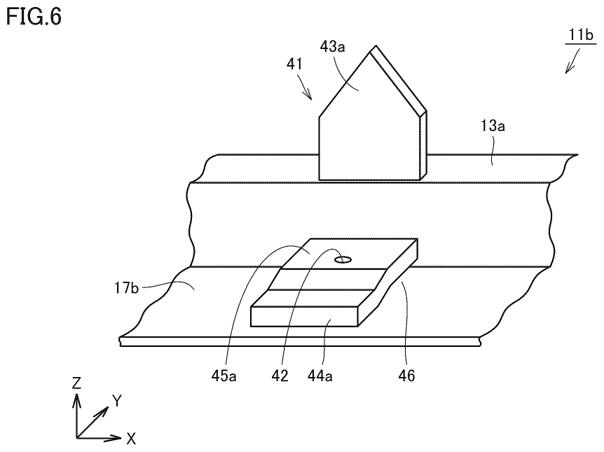

A second embodiment as another embodiment will be described. FIG. 6 is a schematic perspective view partially illustrating a semiconductor device according to a second embodiment. The semiconductor device according to the second embodiment basically has a configuration and advantages similar to those of the first embodiment. The semiconductor device according to the second embodiment, however, is different from that of the first embodiment in terminal configuration.

With reference to FIG. 6, a semiconductor device 11b according to the second embodiment includes a plate-shaped terminal 41 electrically connected to a circuit pattern. The terminal 41 includes a third region 43a attached to a wall portion 13a, a fourth region 44a located inside a frame member and directly connected to a circuit pattern, specifically a circuit plate 17b included in the circuit pattern, and a fifth region 45a located between the third region 43a and the fourth region 44a. An inner wall surface of a wall portion 13a extends in a thickness direction of a substrate. A distance between the inner wall surface of the wall portion 13a and the circuit pattern is 500 μm or less. A gap 46 is present between the fifth region 45a and the circuit plate 17b of the circuit pattern. The fifth region 45a has a through hole 42 penetrating the substrate in the thickness direction thereof.

In the thus-configured semiconductor device 11b, the distance between the inner wall surface 27 of the wall portion 13a and the circuit plate 17b of the circuit pattern 16 is 500 μm or less, and the fourth region 44a of the terminal 41 is directly connected to the circuit plate 17b of the circuit pattern 16. Thus, the device configuration can be simplified to be miniaturized. In addition, members such as wires are unnecessary to connect the terminal 41 to the circuit plate 17b of the circuit pattern 16 so that inductance can be reduced without the need for wiring. The thus-configured semiconductor device 11b can be easily miniaturized and can reduce inductance.

In the semiconductor device 11b described above, the fifth region 45a having the gap 46 between the fifth region 45a and the circuit pattern 16 has the through hole 42 penetrating the substrate 15 in the thickness direction thereof. Such a gap 46 can be formed in, for example, ultrasonic bonding during fabrication based on design with consideration of tolerance. Thus, even if bubbles are mixed in filling a frame member 13 with an encapsulant 14 so that the gap 46 contains bubbles, bubbles are released through the through hole 42 in the fifth region 45a during release of bubbles, thereby eliminating bubbles from the encapsulant 14. Accordingly, it is possible to suppress durability degradation of the semiconductor device 11b by reducing retention of bubble in a lower portion of the terminal 41. As a result, the semiconductor device 11b can enhance reliability.

### Other Embodiments

In the embodiments described above, at least one of the second region and the circuit pattern or the fourth region and the circuit pattern may be connected to each other by welding, ultrasonic bonding, a conductive binder, or soldering. This connection enables connection between the second region and the circuit pattern with further ensured conductivity.

In the embodiments described above, at least one of the first region or the third region may include a portion inserted in the wall portion. With this configuration, terminals can be fixed to wall portions of the frame member beforehand, and thus, the terminals can be more securely attached to the frame member.

It should be understood that the embodiments disclosed here are illustrative and non-restrictive in every respect. The scope of the present invention is defined by the terms of the claims, rather than the description above, and is intended to include any modifications within the scope and meaning equivalent to the terms of the claims.

### DESCRIPTION OF REFERENCE NUMERALS

11a, 11b semiconductor device, 12 base plate, 12a first surface, 13 frame member, 13a wall portion (first wall portion), 13b wall portion (second wall portion), 13c wall portion (third wall portion), 13d wall portion (fourth wall portion), 14 encapsulant, 15 substrate, 16 circuit pattern, 17a, 17b, 17c, 17d, 17e, 17f, 17g circuit plate, 18a first portion, 18b second portion, 18c third portion, 19a, 19b, 19c, 19d main terminal, 20 case, 21a, 21b, 21c, 21d, 21e, 21f semiconductor chip, 22a, 22b, 22c, 22d, 22e, 22f, 23a, 23b, 23c, 23d, 23e, 23f, 24a, 24b, 24c, 24d, 24e, 24 wire, 27 inner wall surface, 29a, 29b, 29c, 29d control terminal, 31a, 31b, 31c, 31d, 33a first region, 32a, 32b, 32c, 32d, 34a second region, 41 terminal, 42 through hole, 43a third region, 44a fourth region, 45a fifth region, 46 gap, D distance.

1. A semiconductor device comprising:
a substrate with a circuit pattern;
a semiconductor chip mounted on the circuit pattern and electrically connected to the circuit pattern;
a frame member including a wall portion; and
a plate-shaped terminal electrically connected to the circuit pattern, wherein the wall portion surrounds the substrate,
the terminal includes
a first region attached to the wall portion, and
a second region located inside the frame member,
a distance between an inner wall surface of the wall portion and the circuit pattern is 500 μm or less, and
the second region is directly connected to the circuit pattern.

2. A semiconductor device comprising:
a substrate with a circuit pattern;
a semiconductor chip mounted on the circuit pattern and electrically connected to the circuit pattern;
a frame member including a wall portion; and
a plate-shaped terminal electrically connected to the circuit pattern, wherein
the wall portion surrounds the substrate,
terminal includes
a third region attached to the wall portion,
a fourth region located inside the frame member and directly connected to the circuit pattern, and
a fifth region located between the third region and the fourth region,
a distance between an inner wall surface of the wall portion and the circuit pattern is 500 μm or less, and
a gap is present between the fifth region and the circuit pattern, and
the fifth region includes a through hole penetrating the substrate in a thickness direction of the substrate.

3. The semiconductor device according to claim 1, wherein an inner wall surface of the wall portion is in contact with the circuit pattern.

4. The semiconductor device according to claim 1, wherein the second region and the circuit pattern is connected to each other by welding, ultrasonic bonding, a conductive binder, or soldering.

5. The semiconductor device according to claim 1, further comprising a base plate which contacts the substrate and to which the frame member is attached.

6. The semiconductor device according to claim 1, further comprising an encapsulant that fills space surrounded by the wall portion.

7. The semiconductor device according to claim 1, wherein the terminal includes a control terminal that controls operation of the semiconductor chip.

8. The semiconductor device according to claim 1, wherein the terminal includes a main terminal electrically connecting the semiconductor device to outside.

9. The semiconductor device according to claim 1, wherein an outer wall surface of the substrate is in contact with the inner wall surface of the wall portion.

10. The semiconductor device according to claim 1, wherein the first region includes a portion inserted in the wall portion.

11. The semiconductor device according to claim 1, wherein the semiconductor chip includes a SIC transistor chip.

12. The semiconductor device according to claim 1, wherein the inner wall surface of the wall portion extends in a thickness direction of the substrate.

13. The semiconductor device according to claim 2, wherein an inner wall surface of the wall portion is in contact with the circuit pattern.

14. The semiconductor device according to claim 2, wherein the fourth region and the circuit pattern is connected to each other by welding, ultrasonic bonding, a conductive binder, or soldering.

15. The semiconductor device according to claim 2, further comprising a base plate which contacts the substrate and to which the frame member is attached.

16. The semiconductor device according to claim 2, further comprising an encapsulant that fills space surrounded by the wall portion.

17. The semiconductor device according to claim 2, wherein the terminal includes a control terminal that controls operation of the semiconductor chip.

18. The semiconductor device according to claim 2, wherein the terminal includes a main terminal electrically connecting the semiconductor device to outside.

19. The semiconductor device according to claim 2, wherein an outer wall surface of the substrate is in contact with the inner wall surface of the wall portion.

20. The semiconductor device according to claim 2, wherein the third region includes a portion inserted in the wall portion.
